(19) United States
(12) Patent Application Publication
(10) Pub. No.: US 2023/0366955 A1
(43) Pub. Date: Nov. 16, 2023

(54) SYSTEM AND METHOD FOR SUPPRESSING LOW FREQUENCY MAGNETIC NOISE IN MAGNETO-RESISTIVE SENSORS

(71) Applicants: COMMISSARIAT A L'ENERGIE ATOMIQUE ET AUX ENERGIES ALTERNATIVES, PARIS (FR); CENTRE NATIONAL DE LA RECHERCHE SCIENTIFIQUE, PARIS CEDEX 16 (FR)

(72) Inventors: Aurélie SOLIGNAC, GIF SUR YVETTE (FR); Mafalda JOTTA GARCIA, PARIS (FR); Julien MOULIN, GIF SUR YVETTE (FR); Steffen WITTROCK, GENTILLY (FR); Paolo BORTOLOTTI, PALAISEAU CEDEX (FR); Vincent CROS, PARIS (FR); Claude FERMON, GIF SUR YVETTE (FR); Myriam PANNETIER-LECOEUR, GIF SUR YVETTE (FR)

(21) Appl. No.: 18/247,001

(22) PCT Filed: Sep. 30, 2021
(86) PCT No.: PCT/EP2021/076939

§ 371 Date: Mar. 28, 2023

(30) Foreign Application Priority Data
Oct. 1, 2020 (FR) FR2010041

(51) Int. Cl. G01R 33/00; G01R 33/09

(52) U.S. Cl. CPC G01R 33/0041; G01R 33/093; G01R 33/0017

(57) ABSTRACT

A system for suppressing low frequency magnetic noise from magnetoresistive sensors, the system including at least one magneto-resistive sensor including a free magnetic layer having a variable magnetisation, and a system for modifying magnetisation of the free magnetic layer, wherein the system for modifying magnetisation of the free layer is adapted to drive dynamics of the magnetisation of the free magnetic layer.

### TECHNICAL FIELD OF THE INVENTION

The invention belongs to the field of magnetoresistive sensors for measuring magnetic fields. One object of the invention is a system for suppressing low-frequency magnetic noise from magneto-resistive sensors. Another object of the invention is a method for suppressing low-frequency magnetic noise from magneto-resistive sensors.

Magnetoresistive sensors include, for example, Giant Magnetoresistance (GMR) and Tunnel Magnetoresistance (TMR) sensors, but the invention relates to any magnetoresistive type magnetic field sensor.

### TECHNOLOGICAL BACKGROUND OF THE INVENTION

Magnetoresistive (MR) sensors with tunnel magnetoresistance (TMR) or giant magnetoresistance (GMR) are typically comprised of two ferromagnetic layers separated by a non-magnetic spacer, being respectively metallic for a GMR and insulating for a TMR. One ferromagnetic so-called “reference” layer has a magnetisation that is independent of the magnetic field to be detected. The other, so-called “free” magnetic layer has a magnetisation configuration that is influenced by the magnetic field to be detected.

The performance of MR sensors is often limited by the presence of noise of magnetic origin, due to magnetic fluctuations of the free magnetic layer of the stacks. A reduction of this magnetic noise would allow a substantial improvement in the performance of MR sensors, for example in automotive applications or in non-destructive testing.

Sources of low-frequency noise can be intrinsic, such as fluctuations in magnetisation for magnetic sensor devices, the incidence of defects and/or inhomogeneities in the magnetic layers or electrical fluctuations in the tunnel barrier, due especially to the manufacturing method. In addition to intrinsic origins, external fluctuations in the driving DC current or the magnetic field applied can also contribute to measurement noise.

Ways of reducing electrical noise in MR sensors are known (see for example patent application EP3631484 “System and method for suppressing low frequency noise in magnetoresistive sensors” filed on behalf of the applicant).

In an attempt to reduce magnetic noise, usually, techniques used are based on improving properties of MR stacks such as layer growth, materials used, or couplings (see for example “Optimizing magnetoresistive sensor signal-to-noise via pinning field tuning” by J. Moulin et al. published in Applied Physics Letters in 2019). This allows for obtaining a stabilisation of the magnetisation of the free magnetic layer.

Another approach used is to put a large number of MR sensors in series in order to increase the magnetic volume of the whole and thus reduce magnetic noise.

However, these solutions known to the skilled person are not satisfactory. For example, with the work on stacks, especially for TMR sensors, the main difficulty is to achieve a stabilised free magnetic layer sensitive to the external field. Furthermore, in the case of a device with a large number of MR elements in series, the power consumption of the sensor significantly increases as well as the overall size of the final system.

In other words, there is currently no way of reducing magnetic noise in MR sensors for keeping good sensitivity of the free layer and linear response of the sensor over a wide range of magnetic fields to be measured.

### SUMMARY OF THE INVENTION

The invention aims at solving at least partially the above mentioned problems by providing a low-frequency magnetic noise suppression system with a small overall size, including low power consumption and exhibiting a linear response over a wide range of external magnetic fields.

To this end, a first object of the invention is a system for suppressing low frequency magnetic noise from magnetoresistive sensors, said system comprising:
at least one magneto-resistive sensor comprising a free magnetic layer having a variable magnetisation;
means for modifying magnetisation of the free magnetic layer;
   said system for suppressing low frequency magnetic noise being characterised in that the means for modifying magnetisation of the free magnetic layer are adapted to drive dynamics of the magnetisation of the free magnetic layer.

By magnetoresistive sensor, it is meant any sensor with a resistance that depends on an external magnetic field and is based on spin electronics. MR sensors have a magnetic reference layer and a free magnetic layer, whose magnetisation is sensitive to the magnetic field to be measured. Examples of magnetoresistive sensors are the GMR or TMR sensors introduced above.

By magnetic noise suppression, it is meant a reduction or suppression of magnetic noise. The magnetic noise can for example be halved by virtue of the sensor according to the invention. The reduction of magnetic noise by virtue of the sensor according to the invention may also be greater than a factor of two, up to complete suppression of magnetic noise.

By means for modifying magnetisation of the free layer, it is understood means adapted to modify a magnetisation property of the free layer. For example, such means may include means for injecting a direct or alternating current into the magnetoresistive sensor or even means for applying an oscillating magnetic field. The means for modifying magnetisation of the free layer may also include means adapted to cause local heating to modify magnetisation of the free layer. For example, the means for modifying magnetisation of the free layer may comprise a pulsed light source such as a laser.

By magnetisation dynamics, it is meant a variation over time of a magnetisation property of the free layer. For example, the means for changing magnetisation of the free layer may be adapted to apply a torque to the magnetisation of the free layer. In this case, the torque may be generated by spin transfer between magnetic layers present in the sensor due to a current or by Zeeman effect due to a magnetic field.

According to one embodiment, the magnetisation of the free layer has a spatially inhomogeneous configuration. In other words, the magnetisation of the free layer has a spatially variable intensity and direction.

According to one embodiment, the magnetisation of the free layer has a vortex-like configuration. A vortex-like configuration is a spatially inhomogeneous magnetic configuration in which the magnetisation has a different orientation depending on the point at which it is located. The magnetisation lies in the plane of the free magnetic layer and rotates either clockwise or counterclockwise, the circular behaviour of the magnetisation being explained by the spontaneous minimisation of the leakage field. Furthermore, a singularity is observed in the centre of the vortex in a zone called the “vortex core” in which the magnetisation points out of the plane.

In this case the dynamics of the free layer magnetisation comprises moving the vortex core, due to the torque(s) applied by the magnetisation modifying means. According to one embodiment, moving the vortex core is made in the plane of the free layer. The dynamics of the magnetisation of the free layer may for example induce a gyrotropic movement of the vortex core, that is a movement of the vortex core about its equilibrium position.

Advantageously, the dynamisation of the magnetic vortex magnetisation prevents it from being trapped at sites or defects giving rise to magnetic noise.

In other words, driving dynamics of the vortex core over a wide range of frequencies makes it possible to reduce or even suppress low-frequency noise of magnetic origin in MR sensors. The noise related to this reduction is, for example, 1/f noise or random telegraph noise (RTN).

Alternatively, the magnetisation of the free layer may have configurations comprising several vortices. According to another embodiment of the invention, the free layer comprises a stack comprising a plurality of magnetic layers having a free magnetisation, each layer of the stack having a spatially inhomogeneous magnetisation. For example, each layer of the stack may exhibit a magnetisation having one or more vortices.

According to another embodiment, the magnetisation of the free layer has a configuration of anti-vortex, vortex anti-vortex pair, skyrmion type or a configuration having topological properties close to that of a vortex.

According to one embodiment, the magnetic noise suppression system according to the invention comprises a plurality of magneto-resistive sensors. In this case, the free layers of different sensors may be coupled to each other by means of the leakage magnetic field, an injected current or an external magnetic field.

According to one embodiment, the means for modifying magnetisation of the free magnetic layer comprise means adapted to inject a direct or alternating electric current into the MR sensor. Alternatively, the means for modifying magnetisation of the free layer may comprise means adapted to apply an oscillating external magnetic field preventing it from being trapped and reducing magnetic noise. In the following, direct current or DC and alternating current or AC will be referred to interchangeably.

By trapping, it is meant magnetic trapping of the magnetisation.

Advantageously, the injection of an electric current into the MR sensor generates a spin transfer torque which acts on the magnetisation of the free magnetic layer, preventing it from being trapped and reducing the magnetic noise.

Advantageously, the application of an oscillating magnetic field creates a torque on the magnetisation of the free magnetic layer by the Zeeman effect, preventing it from being trapped and reducing magnetic noise.

Advantageously, the reduction of low frequency magnetic noise allows the signal to noise ratio to be increased when measuring an applied magnetic field, while increasing reliability and accuracy of the measurement.

Advantageously, the system according to the invention makes it possible to obtain MR sensors with low noise and a linear response over a wide range of magnetic fields to be measured.

The dynamics of the magnetisation can be induced in two different regimes: a subcritical regime and a self-oscillating regime. In the first case, the torque applied by the means of modifying the free magnetisation is less than the damping of the system. In the second case, the applied torque exceeds the system damping and generates self-sustained oscillations of the vortex core.

In all embodiments of the invention, the injection of an electric current or the application of an oscillating magnetic field is only required upon performing the measurement using the MR sensor.

It is important to note that the control of vortex dynamics has various high frequency applications, by virtue of its non-linearity, such as components for radio frequency communication. The vortex dynamics can be induced by applying an external RF field or by injecting a DC or AC current into the MR sensor. These means induce a torque on the magnetisation of the vortex, by spin transfer or Zeeman effect, which starts to oscillate. It is not known to use dynamics to reduce low frequency noise in vortices. Furthermore, such dynamics control has never been used for magnetic sensors using in particular vortices for linearisation. A linear response of the sensor according to the invention over a wide range of magnetic fields is also obtained for different magnetic configurations, for example having several coupled vortices.

Advantageously, the operation of the modulation means only during the measurement allows the power consumption by the system according to the invention to be limited.

Advantageously, when the vortex core dynamics is driven by a current injected into the sensor, the same current can be used to read the magnetic response of the sensor without an additional power source. This reduces both the overall size and power consumption of the system according to the invention.

The system according to the invention may also have one or more of the following characteristics, considered individually or according to any technically possible combinations:
The magnetisation of the free magnetic layer includes a spatially inhomogeneous configuration;
the magnetisation of the free magnetic layer is in a vortex configuration;
the magnetisation of the free magnetic layer includes several vortices;
the free magnetic layer comprises a stack of free magnetic layers, each free magnetic layer in the stack including a spatially inhomogeneous magnetisation;
the magnetisation of each layer of the stack includes one or more vortices;
the means for modifying magnetisation of the free magnetic layer are adapted to drive dynamics of the magnetisation of the free magnetic layer including moving the vortex;
the means for modifying magnetisation of the free magnetic layer comprises means for injecting a direct electric current into the magnetoresistive sensor;
the means for modifying magnetisation of the free magnetic layer comprises means for injecting an alternating electric current into the magnetoresistive sensor;
the means for modifying magnetisation of the free magnetic layer comprises means for generating an oscillating magnetic field;
the current density injected into the magnetoresistive sensor is greater than a predetermined critical density; and
the oscillating magnetic field applied is greater than a predetermined critical field;
the system according to the invention further comprises means adapted to measure the resistance of the magnetoresistive sensor.

Another object of the invention is a method for suppressing low frequency magnetic noise associated with the measurement of an external magnetic field by a measurement device comprising a magneto-resistive sensor, said magneto-resistive sensor comprising a free magnetic layer having a variable magnetisation.

The method according to the invention comprises the following steps of:
Placing the free magnetic layer of the magnetoresistive sensor into a predetermined magnetisation state;
driving, using means for modifying magnetisation of the free magnetic layer, dynamics of the magnetisation of the free magnetic layer.

The method according to the invention may also have one or more of the following characteristics, considered individually or according to any technically possible combinations:
the method further comprises a step of measuring the resistance of the magnetoresistive sensor;
the magnetisation of the free magnetic layer is in a vortex configuration and the step of driving dynamics of the magnetisation of the free magnetic layer includes a step of moving the vortex;
the method further comprises a step of measuring the resistance of the magnetoresistive sensor;
the steps of producing dynamics of the magnetisation of the free magnetic layer and measuring the resistance of the magnetoresistive sensor are performed simultaneously.

Advantageously, this reduces power consumption of the method according to the invention.

Advantageously, the implementation of the method according to the invention makes it possible to reduce or even suppress low frequency magnetic noise associated with the measurement of an external magnetic field. This is possible by virtue of the fact that the dynamics driven prevent trapping of the free layer magnetisation, eliminating one of the causes of low frequency noise in MR sensors.

### BRIEF DESCRIPTION OF THE FIGURES

Further characteristics and advantages of the invention will become clearer from the description given below, by way of indicating and in no way limiting purposes, with reference to the appended figures, among which:

FIG. 1A shows one embodiment of the system according to the invention.

FIG. 1B shows one embodiment of the system according to the invention.

FIG. 1C shows one embodiment of the system according to the invention.

FIG. 2 shows one exemplary embodiment of a stack of layers used for making a GMR or TMR type MR sensor.

FIG. 3 shows the noise response of the system according to the invention.

FIG. 4 shows the resistance response of the system according to the invention.

FIG. 5 shows the noise reduction as a function of the strength of the oscillating magnetic field applied in the embodiment represented in FIG. 1C.

FIG. 6 shows the noise reduction as a function of the frequency of the oscillating magnetic field applied in the case of the embodiment represented in FIG. 10.

FIG. 7 shows the reduction of magnetic noise as a function of the frequency of the alternating electric current injected in the case of the embodiment represented in FIG. 1B.

FIG. 8 illustrates the steps of the method for suppressing low frequency magnetic noise according to the invention.

### DETAILED DESCRIPTION OF THE INVENTION

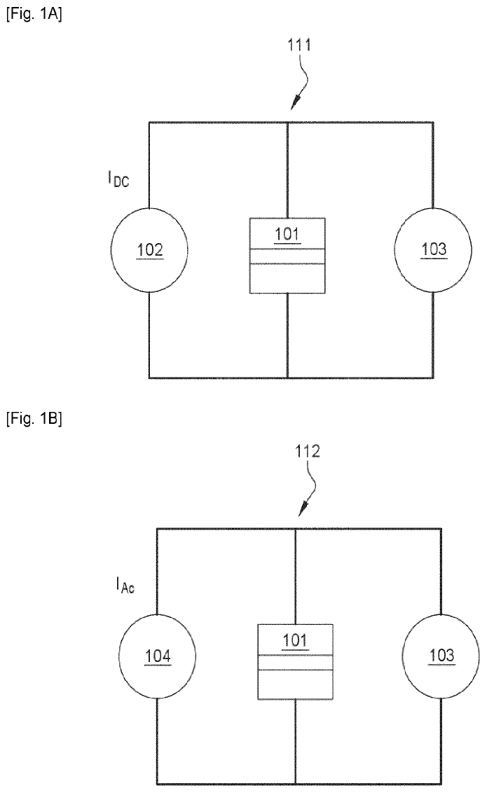

FIG. 1A shows a first embodiment 111 of the low frequency magnetic noise suppression system according to the invention. The system 111 comprises an MR sensor 101 and means 102 for modifying magnetisation of the free magnetic layer of the MR sensor 101. According to this embodiment, the means 102 comprise means for injecting a direct electric current I_{DC} into the MR sensor 101. The low frequency magnetic noise suppression system 111 may further comprise means 103 for measuring the resistance of the MR sensor 101.

Advantageously, in the embodiment 111, the MR sensor 101 is supplied with a direct current I_{DC} which makes it possible to drive dynamics of the magnetisation in the free magnetic layer of the sensor 101 and thus to reduce or even suppress the noise of magnetic origin. The measurement of this current I_{DC} or of the voltage across the sensor 101 gives access to the variation of the resistance of the sensor 101 and thus to the magnetic signal to be detected.

According to one embodiment, the dynamics of the magnetisation of the free layer of the system 111 can be sustained. This mode of operation is also referred to as the self-oscillating regime. Alternatively, the system may operate in a damped or subcritical regime. To achieve the sustained oscillation regime, it is necessary to inject a current density greater than a critical density. The critical current density required to reach the self-oscillation regime is determined by measuring the radio frequency power emitted by the sensor when a DC current is injected.

FIG. 1B illustrates a second embodiment 112. The low frequency magnetic noise suppression system 112 comprises an MR sensor 101 and means 104 for modifying magnetisation of the free layer of the MR sensor 101. The means 104 are adapted to inject an alternating electric current I_{AC} into the MR sensor 101. The low frequency magnetic noise suppression system 112 may further comprise means 103 for measuring the resistance of the MR sensor 101.

Advantageously, in the embodiment 112, the MR sensor 101 is supplied with an alternating electric current I_{AC} which makes it possible to drive dynamics in the free layer of the sensor 101 and thus to reduce or even suppress the noise of magnetic origin. The measurement of this current I_{AC} or of the voltage across the sensor 101 makes it possible to measure variation of the resistance of the sensor 101 and thus the intensity of the magnetic field to be detected.

According to one embodiment, the dynamics of the magnetisation of the free layer of the system 112 can be sustained. This mode of operation is also referred to as the self-oscillating regime. Alternatively, the system may operate in a damped or subcritical regime. To achieve the sustained oscillation regime, it is necessary to inject a current density greater than a critical density.

FIG. 1C illustrates a third embodiment 113. The low frequency magnetic noise suppression system 113 comprises an MR sensor 101 and means 106 for modifying magnetisation of the free layer of the MR sensor 101. The means 106 are adapted to apply an oscillating magnetic field in proximity to the MR sensor 101. The low frequency magnetic noise suppression system 112 may further comprise means 105 for injecting a DC or AC current into the MR sensor 101.

Advantageously, the means 105 for injecting an AC or DC current allows measurement of the voltage across the sensor. The variation of the resistance of the sensor 101 thus makes it possible to measure the magnetic field to be detected. The low frequency magnetic noise suppression system 113 may further comprise means 103 for measuring the resistance of the MR sensor 101.

The means 106 for modifying magnetisation of the free layer of the sensor may comprise coils or a field line close to the sensor which are powered by an electrical current oscillating at radio frequencies or RF.

According to one embodiment, the dynamics of the free layer magnetisation of the system 113 may be sustained. This mode of operation is also referred to as the self-oscillating regime. Alternatively, the system may operate in a damped or subcritical regime. To achieve the sustained oscillation regime, it is necessary to apply an oscillating magnetic field greater than a critical oscillating field.

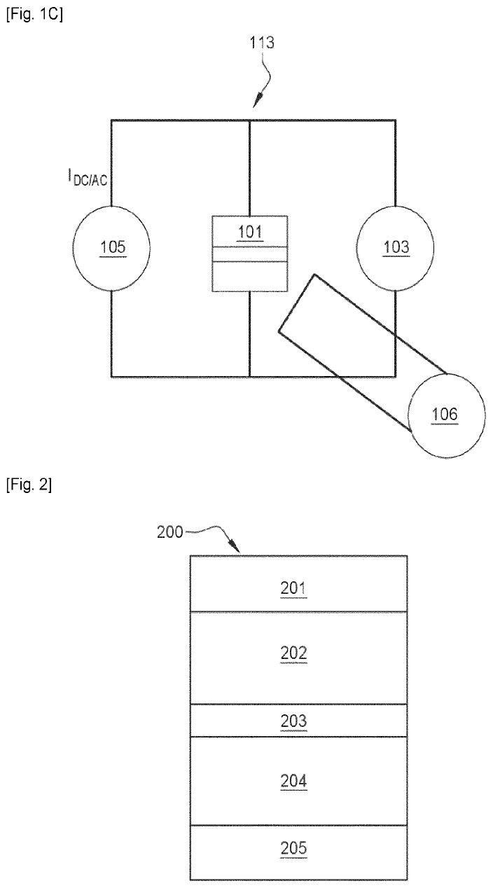

FIG. 2 shows a typical stack 200 of MR sensor consisting of a cover layer 201, a first ferromagnetic layer 202 having a free magnetisation, a non-magnetic layer 203, a second ferromagnetic layer 204 having a fixed magnetisation and a buffer layer 205. The two ferromagnetic layers 202 and 204 are thus separated by a non-magnetic spacer 203, being respectively metallic for a GMR and insulating for a TMR. The layers represented in FIG. 2 may each include a stack of layers, including different materials and thicknesses chosen to achieve the desired function.

The second ferromagnetic layer 204, referred to as the “reference” layer, has a magnetisation independent of the magnetic field to be detected. The first so-called “free” ferromagnetic layer 202 has a magnetisation that follows the magnetic field to be detected. The buffer layer allows re-growth on the substrate. The protective layer protects the sensor from oxidation especially and allows electrical contacts to be continued. The reference layer, the free layer, the protective layer and the buffer layer may be comprised of one or more layers.

According to one embodiment, the first free ferromagnetic layer 202 comprises a plurality of free magnetic layers. The free magnetic layers may be spaced apart two by two, for example by means of a non-magnetic layer. Said non-magnetic layer implements for example an indirect coupling between the two adjacent free magnetic layers. According to an alternative, the free magnetic layers may be in contact two by two, so as to improve the measurable magnetoresistance signal across the stack. Said free magnetic layers are in partial or total contact. When the free magnetic layers are in direct contact, the dynamics of the resulting magnetisation is also improved.

According to one embodiment, the MR sensor is a TMR sensor comprised of a Si/SiO2 type stack for the substrate/buffer layer/PtMn(15)/CoFe₂₉ (2.5)/Ru (0.85)/CoFeB (1.6)/CoFe_30 (2.5)/MgO (1)/FeB (6)/MgO (1)/cover layer. The numbers in brackets here indicate the layer thicknesses in nm. This stack can be fabricated into a pillar of typically 300 nm diameter connected by metal contacts. The magnetisation of the reference layer PtMn (15)/CoFe₂₉ (2.5)/Ru (0.86)/CoFeB (1.6)/CoFe₃₀ (2.5) is locked in the plane of the thin layers and the magnetisation of the free FeB layer (6) is stabilised in a vortex state by virtue of its thickness and the size of the pad.

This vortex configuration is interesting because it allows a linear response of the sensor as a function of the field over a wide range of magnetic fields to be measured. The size of the pads and the MR stacking allow the field response and linearity range to be controlled. The 1/f and RTN noise in these sensors sharply increases over this linearity range and is of magnetic origin, which limits performance of the sensor over its operating range. Advantageously, the use of the system according to the invention makes it possible to reduce the noise associated with this type of sensor while keeping linearity over a wide range of magnetic fields to be measured.

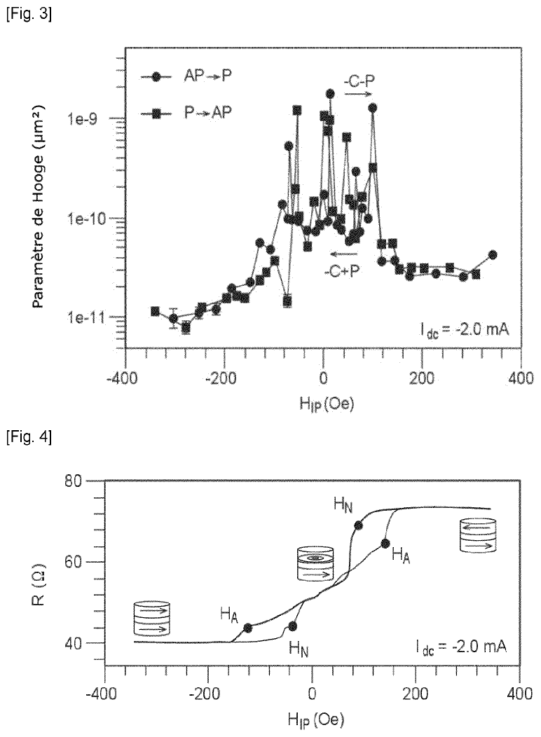

FIG. 3 shows the noise response measured on TMR pillars of 350 nm diameter and comprising the stack of layers described in paragraphs [0057-0059]. FIG. 3 shows the rise in magnetic noise in the sensor operating regime, that is around zero field and over the linearity range of the sensor, with this magnetic noise being suppressed at high magnetic field. The graph in FIG. 3 shows the Hooge parameter as a function of the external magnetic field applied in the plane of the thin layers and in the direction parallel to the direction of the magnetisation of the reference layer, that is along the sensitivity axis of the sensor. The Hooge parameter determines the 1/f noise amplitude and is extracted from the noise spectral density measurement. The circles indicate the transition from the state of the sensor with the free layer magnetisation parallel to the reference layer magnetisation P to the state of the sensor with the two anti-parallel magnetisations AP. The squares illustrate the reverse transition from the AP to the P configuration. The chirality and polarisation of the vortex are indicated by the letters P and C respectively. Noise reduction has been verified for all 4 states of the vortex: +P, −P, +C and −C.

FIG. 4 illustrates the resistance response under the same conditions as those set in FIG. 3. The sensor response is linear over the range of −30 Oe to 80 Oe (where 1 Oersted is equal to 1000/(4π) A□m⁻¹ in international system units).

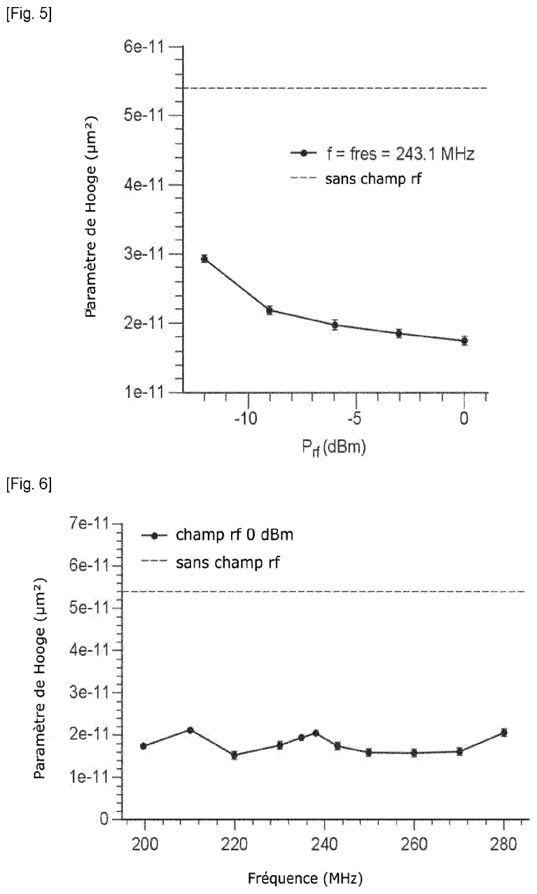

FIG. 5 illustrates the reduction in low frequency magnetic noise by virtue of using the system according to the invention in the configuration of FIG. 1C.

The graph in FIG. 5 represents the Hooge parameter as a function of the strength of the applied RF magnetic field to drive a vortex dynamics of the free layer magnetisation according to the invention. The dots connected by a solid line represent the Hooge parameter measured in the configuration 113 of FIG. 1C. The dashed line represents the magnetic noise measured without an applied magnetic field, that is when the system according to the invention is not used. FIG. 5 thus shows that the system according to the invention is effective in reducing low frequency magnetic noise.

FIG. 6 illustrates the Hooge parameter as a function of the frequency of the oscillating magnetic field applied to drive a vortex dynamics of the free layer magnetisation according to the invention. The dots connected by a solid line represent the Hooge parameter measured in the configuration 113 of FIG. 1C. The dashed line represents the magnetic noise measured without an applied magnetic field, that is when the system according to the invention is not used. As in the case of FIG. 5, FIG. 6 thus shows that the system according to the invention is effective in reducing low frequency magnetic noise.

In the cases of FIGS. 5 and 6, the MR sensor is in the self-oscillating regime with an applied DC current of 8 mA and a perpendicular magnetic field of 4 kOe (where 1 Oersted is equal to 1000/(4π) A□m⁻¹ in international system units).

According to one embodiment, an AC line positioned above the free layer is used to apply an oscillating magnetic field parallel to the plane of the disc with an RF current injected into the line 106 of FIG. 1C. It is possible to further reduce the noise, by moving into the self-oscillation regime, allowing the noise value in the parallel state of the sensor magnetisations (the lowest in general) to be approached while keeping the advantage of the linearity of vortex-based TMR sensors.

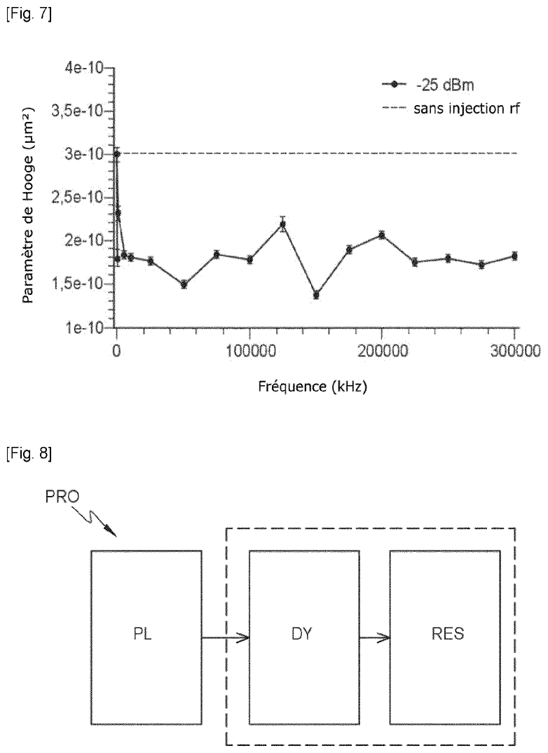

FIG. 7 illustrates the Hooge parameter as a function of the frequency of the AC electric current injected into the MR sensor according to the configuration 112 illustrated in FIG. 1B. The measurement was made for an RF current in the sensor having power −25 dBm, corresponding to about 3 μW. As in FIGS. 5 and 6, the dots connected by a solid line correspond to the measured Hooge parameter and show the noise reduction compared to the dashed line, corresponding to the case when the system according to the invention is not used.

Measurements illustrated in FIGS. 5, 6 and 7 indicate that the system according to the invention allows the reduction of magnetic noise by a factor 3 in the configurations considered here. A gain of a factor 3 is thus directly obtained on the signal to noise ratio. It should be noted that in order to obtain this gain of a factor 3 on the signal to noise ratio without using additional AC excitation, it would be necessary to increase averaging of the measurement by a factor 10.

Advantageously, the measuring means 103 is configured to measure the variation in sensor resistance by measuring a low frequency component of a signal from the sensor. The signal from the sensor is, for example, an electric voltage or an electric current. The low frequency component of the signal advantageously has a maximum frequency of less than 1 MHz, for example less than 50 kHz.

It is known to the person skilled in the art to measure the value of an external magnetic field by separating a high frequency component from a signal from a sensor and determining the frequency shift of the high frequency component when the external field is applied or not. The high frequency component of said signal has a frequency greater than 1 MHz, for example in the order of a few gigahertz. This method does not measure the variation in resistance of the sensor, but only the variation in frequency of the high frequency component. This method, known to the person skilled in the art, implements, for example, a polarisation tee to separate the high frequency component from the low frequency component.

The measuring means 103 according to the invention, on the other hand, makes it possible to measure directly the variation in the resistance of the sensor. It also has the advantage of not resorting to a polarisation tee and is therefore simpler. A low-pass filter can be used to eliminate the high frequency component of the signal from the sensor.

FIG. 8 illustrates the method PRO for suppressing low frequency magnetic noise associated with the measurement of an external magnetic field by a measurement device comprising a magneto-resistive sensor.

The method PRO comprises a first step PL comprising placing the free magnetic layer of the magneto-resistive sensor into a predetermined state of magnetisation.

Advantageously, this step makes it possible to determine the magnetisation state of the free layer of the MR sensor. Placing the magnetisation of the free layer into a well-determined state is essential to be able to effectively drive its dynamics during the implementation of the method according to the invention.

According to one embodiment, the state of magnetisation of the free layer is a magnetisation in a vortex configuration.

The method PRO further comprises a step DY of driving dynamics of the magnetisation of the free magnetic layer.

Advantageously, this step reduces low frequency magnetic noise by preventing the magnetisation of the free magnetic layer from being trapped in defects in the layer.

When the magnetisation of the free magnetic layer is in a vortex configuration, the dynamics of the free layer may include moving the core of the vortex in the plane of the layer, preventing it from being trapped and reducing low frequency magnetic noise.

According to one embodiment, the method PRO according to the invention further comprises a step RES of measuring the resistance of the MR sensor. Advantageously, this step makes it possible to measure the external magnetic field.

According to one embodiment, the step DY of driving dynamics of the free magnetic layer and the step RE of measuring the resistance of the MR sensor are performed simultaneously. In other words, the dynamics of the free layer magnetisation is driven only during the measurement of the external magnetic field.

Advantageously, this makes it possible to limit power consumption during the implementation of the method according to the invention, since the dynamics of the magnetisation of the free layer is driven only during the operation of measuring the external magnetic field.

Advantageously, when the AC dynamics of the vortex core is produced by a current injected into the sensor, the same current can be used to read the magnetic response of the sensor without an additional power source.

The PRO method according to the invention may further comprise a step of determining conditions necessary to drive dynamics of the free layer magnetisation.

In other words, the PRO method according to the invention may comprise a step of determining properties of the free layer magnetisation modifying means in order to achieve the desired dynamics of the free layer magnetisation.

For example, the current and/or magnetic field and/or frequency and/or amplitude conditions necessary to drive free layer magnetisation dynamics may be previously measured on the MR sensor using a spectrum analyser.

Typically, for configurations 111 and 112, current densities of a few 10\hat{ }7 A/cm² (that is in the order of one mA for the sensor sizes considered) are required and induce gyrotropic mode frequencies ranging from 100 MHz to 600-700 MHz typically for standard magnetic materials. Note that for coupled vortex systems, it is possible to substantially increase this frequency range. For the configuration 113, an AC field in the order of 100 MHz should be applied.

According to one embodiment, the critical current density of the DC current is greater than or equal to 6.2□10¹⁰ A/m². Thus, the flow of a 6 mA current over a stack as described with reference to FIG. 2, and having for example a diameter of 350 nm, allows a self-oscillation regime of the magnetisation to be reached and thus an improved noise reduction. The frequency range of the magnetisation dynamics corresponding to this critical current density may be the radio frequency range, for example around 300 MHz, for example between 200 MHz and 400 MHz. In the aforementioned example, the frequency of the magnetisation dynamics may be 240 MHz.

1. A system for suppressing low frequency magnetic noise from magnetoresistive sensors, said system comprising:
at least one magnetoresistive sensor comprising a free magnetic layer having a variable magnetisation;
means for modifying the magnetisation of the free magnetic layer,
wherein said means for modifying magnetisation of the free magnetic layer are adapted to drive dynamics of the magnetisation of the free magnetic layer to prevent it from being trapped and reduce low frequency magnetic noise.

2. The system for suppressing low frequency magnetic noise according to claim 1, wherein the magnetisation of the free magnetic layer has a spatially inhomogeneous configuration.

3. The system for suppressing low frequency magnetic noise according to claim 2, wherein the magnetisation of the free magnetic layer is in a vortex configuration.

4. The system for suppressing low frequency magnetic noise according to claim 3, wherein the means for modifying magnetisation of the free magnetic layer are adapted to drive dynamics of the magnetisation of the free layer including moving the vortex.

5. The system for suppressing low frequency magnetic noise according to claim 2, wherein the free magnetic layer includes a stack of free magnetic layers, each free magnetic layer of the stack including a spatially inhomogeneous magnetisation.

6. The system for suppressing low frequency magnetic noise according to claim 5, wherein the free magnetic layers are in direct contact two by two.

7. The system for suppressing low-frequency magnetic noise according to claim 1, wherein the means for modifying magnetisation of the free magnetic layer comprise means for injecting a direct electric current into the magnetoresistive sensor.

8. The system for suppressing low-frequency magnetic noise according to claim 1, wherein the free magnetic layer magnetisation modifying means comprises means for injecting an alternating electric current into the magnetoresistive sensor.

9. The system for suppressing low-frequency magnetic noise according to claim 7, wherein a current density injected into the magnetoresistive sensor is greater than a predetermined critical density, the predetermined critical density being greater than or equal to 6.2·10¹⁰ A/m².

10. The system for suppressing low-frequency magnetic noise according to claim 1, wherein the means for modifying magnetisation of the free magnetic layer comprises means for generating an oscillating magnetic field.

11. The system for suppressing low-frequency magnetic noise according to claim 10, wherein the oscillating magnetic field applied is greater than a predetermined critical field.

12. The system for suppressing low-frequency magnetic noise according to claim 1, further comprising means adapted to measure a resistance of the magnetoresistive sensor.

13. A method for suppressing low frequency magnetic noise associated with the measurement of an external magnetic field by a measurement device comprising a magneto-resistive sensor, said magneto-resistive sensor comprising a free magnetic layer having a variable magnetisation, said method comprising:
a. placing the free magnetic layer of the magneto-resistive sensor into a predetermined magnetisation state;
b. driving, using means for modifying magnetisation of the free magnetic layer, dynamics of the magnetisation of the free magnetic layer to prevent it from being trapped and reduce low frequency magnetic noise.

14. The method according to claim 13, wherein the magnetisation of the free magnetic layer is in a vortex configuration and the driving of the dynamics of the magnetisation of the free magnetic layer includes a step of moving the vortex.

15. The method according to claim 13, further comprising measuring the resistance of the magnetoresistive sensor.

16. The method according to claim 15, wherein the producing of the dynamics of the magnetisation of the free magnetic layer and the measuring of the resistance of the magneto-resistive sensor are performed simultaneously.
